(19) United States
(12) Patent Application Publication
(10) Pub. No.: US 2025/0096802 A1
(43) Pub. Date: Mar. 20, 2025

(54) CONTROL KEY AND ELECTRONIC DEVICE

(71) Applicant: Beijing Zitiao Network Technology Co., Ltd., Beijing (CN)

(72) Inventors: Lei ZHANG, Beijing (CN); Qiang LI, Beijing (CN)

(21) Appl. No.: 18/727,961

(22) PCT Filed: Dec. 8, 2022
(86) PCT No.: PCT/CN2022/137446

§ 371 Date: Jul. 10, 2024

(30) Foreign Application Priority Data
Jan. 13, 2022 (CN) 202210037820.2

(51) Int. Cl. H03K 17/96; H03K 17/975

(52) U.S. Cl. CPC H03K 17/962; H03K 17/975; H03K 2217/96023

(57) ABSTRACT

Embodiments of the disclosure provide a control key and an electronic device. The control key includes: a circuit board having a capacitance detecting circuit therein; a fixing bracket provided with a conductive elastic sheet, the conductive elastic sheet being electrically connected to the circuit board; a control key body disposed on the fixing bracket, an outer side of the control key body having a manipulation surface and an inner side of the control key body being provided with a conductive sheet, the conductive sheet being electrically connected to the conductive elastic sheet, such that the conductive sheet is electrically connected to the capacitance detecting circuit.

### CROSS-REFERENCE OF RELATED APPLICATIONS

The present application is based on Chinese Patent Application No. 202210037820.2, filed on Jan. 13, 2022, and claims priority to the Chinese Patent Application. The entirety of the above-mentioned Chinese Patent Application is incorporated herein by reference.

### FIELD

The present application relates to the field of control keys, and in particular to a control key and an electronic device.

### BACKGROUND

Some capacitive sensing control keys in the related art realize touch detection by setting a spring on a circuit board and covering an outer end of the spring with a cover plate and by changes in charge caused by a user touching the cover plate. However, the detection accuracy of such a capacitive sensing control key needs to be improved.

### SUMMARY

The present application aims to solve at least one of the technical problems existing in the prior art. To this end, one purpose of the present application is to propose a control key that can improve the accuracy of determining touch.

The present application also proposes an electronic device having the above control key.

The control key according to embodiments of a first aspect of the present application comprises: a circuit board having a capacitance detecting circuit therein; a fixing bracket provided with a conductive elastic sheet, the conductive elastic sheet being electrically connected to the circuit board; a control key body disposed on the fixing bracket, an outer side of the control key body having a manipulation surface and an inner side of the control key body being provided with a conductive sheet, the conductive sheet being electrically connected to the conductive elastic sheet, such that the conductive sheet is electrically connected to the capacitance detecting circuit.

According to the embodiments of the present application, by setting a conductive elastic sheet on the fixing bracket, setting the conductive sheet inside the control key body, and using the conductive elastic sheet to realize the electrical connection between the conductive sheet and the circuit board, compared with the technical solution using a conductive spring to realize the electrical connection, the control key not only ensures that the conductive elastic sheet and the circuit board can effectively contact, improving the stability of charge conduction, but also improves the hand feeling when touching, thereby improving the user experience.

According to some embodiments of the present application, the control key body is movable or rotatable relative to the circuit board, and the control key body is adapted to move or rotate upon being pressed.

According to some embodiments of the present application, the conductive elastic sheet is located between the circuit board and the fixing bracket.

According to some embodiments of the present application, the fixing bracket has a mating hole, the conductive elastic sheet has a first connecting hole, the conductive elastic sheet is fixed to the fixing bracket through a fastener, and the fastener passes through the first connecting hole and the mating hole.

According to some embodiments of the present application, an end of the conductive elastic sheet is connected to the fixing bracket to form a fixed end, and the other end of the conductive elastic sheet deviates from the fixing bracket to form a free end, the free end of the conductive elastic sheet is provided with a convex part, and the convex part is in contact with and mates with the circuit board.

According to some embodiments of the present application, the conductive elastic sheet comprises: a first conductive segment fixed on the fixing bracket; a second conductive segment electrically connected to the circuit board; a third conductive segment connected between the first conductive segment and the second conductive segment, the third conductive segment extending obliquely towards a direction approaching the circuit board from the first conductive segment to the second conductive segment.

According to some embodiments of the present application, the conductive sheet is located between the control key body and the fixing bracket.

In some embodiments, the control key body defines an accommodating cavity opening at a side, and an outer surface of a bottom wall of the accommodating cavity is adapted to be touched, wherein the conductive sheet is disposed within the accommodating cavity and mates with an inner surface of the bottom wall of the accommodating cavity.

According to further embodiments of the present application, the control key further comprises: a conductive member disposed on the fixing bracket, both the conductive elastic sheet and the conductive sheet are electrically connected to the conductive member.

In some embodiments, the conductive member forms a conductive shaft, and the control key body is rotatably disposed on the fixing bracket through the conductive shaft.

In some examples, the fixing bracket is provided with a first fixing lug and a second fixing lug arranged at an interval, the first fixing lug has a first fixing hole and the second fixing lug has a second fixing hole, the conductive shaft penetrates the first fixing hole and the second fixing hole.

In some specific examples, the conductive shaft is in an interference fit with a hole wall of at least one of the first fixing hole and the second fixing hole.

In some examples, the inner side of the control key body is provided with a first mounting lug and a second mounting lug arranged at an interval, the first mounting lug has a first mounting hole and the second mounting lug has a second mounting hole, and the conductive shaft passes through the first mounting hole and the second mounting hole

In some embodiments, the conductive member is electrically connected to the conductive elastic sheet through a first conductive wire, and the conductive member is electrically connected to the conductive sheet through a second conductive wire.

In some examples, an end of the conductive elastic sheet is provided with a connecting turnup bent towards the control key body, the connecting turnup has a second connecting hole, and an end the first conductive wire is hung on the second connecting hole and the other end is electrically connected to the conductive member.

The electronic device of the embodiments according to a second aspect of the present application comprises a device body and a control key according to the above embodiments, the control key is disposed in the device body.

Additional aspects and advantages of the application will be set forth in part in the following descriptions, and in part will be apparent from the description, or may be learned by practice of the application.

### BRIEF DESCRIPTION OF THE DRAWINGS

The above and/or additional aspects and advantages of the present application will become apparent and readily understood from the description of embodiments in conjunction with the following drawings, in which:

FIG. 1 is a structural exploded view of a control key according to embodiments of the present application;

FIG. 2 is a schematic structural view of a fixing bracket and a conductive member of the control key according to the embodiments of the present application;

FIG. 3 is a schematic structural view of a conductive elastic sheet of the control key according to the embodiments of the present application;

FIG. 4 is a schematic structural view of a conductive sheet of the control key according to embodiments of the present application;

FIG. 5 is a schematic structural view of the control key body of the control key according to embodiments of the present application.

### REFERENCE NUMERALS

control key 100,
fixing bracket 10, first fixing lug 11, first fixing hole 111, second fixing lug 12, second fixing hole 121, fixing pillar 13, mating hole 131, concave part 14,
circuit board 20,
conductive elastic sheet 30,
first conductive segment 31, first connecting hole 311, connecting turnup 312, second connecting hole 313,
second conductive segment 32,
third conductive segment 33, convex part 331,
first transitional connecting segment 34, second transitional connecting segment 35,
control key body 40, bottom wall 41, side wall 42, limiting turnup 43, first mounting lug 45, first mounting hole 451, second mounting lug 46, second mounting hole 461, third mounting lug 47, third mounting hole 471,
conductive sheet 50, locating hole 51, kerf 52,
conductive member 60, protrusion 61,
first conductive wire 71, second conductive wire 72, and fastener 80.

### DETAILED DESCRIPTION

The embodiments of the present application are described in detail below. Examples of the embodiments are shown in the drawings, in which the same or similar reference numerals throughout represent the same or similar elements or elements with the same or similar functions. The embodiments described below with reference to the drawings are example and are intended to be used to explain the application and are not to be construed as limitations of the application.

The following disclosure provides many different embodiments or examples for implementing the various structures of the present application. To simplify the disclosure of the present application, the components and arrangements of specific examples are described below. Of course, they are merely examples and are not intended to limit the application. Furthermore, the present application may repeat reference numerals and/or letters in different examples. This repetition is for simplicity and clarity purposes and does not in itself indicate the relationship between the various embodiments and/or settings discussed. In addition, the present application provides examples of various specific processes and materials, but one of ordinary skill in the art will recognize the applicability of other processes and/or the use of other materials.

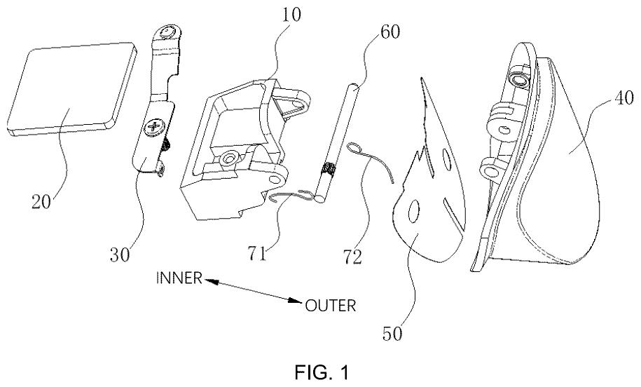

The control key 100 according to embodiments of the present application is described below with reference to FIGS. 1-5.

As shown in FIG. 1, the control key 100 according to the embodiments of the present application includes a circuit board 20, a fixing bracket 10 and a control key body 40.

The circuit board 20 has a capacitance detecting circuit therein, the fixing bracket 10 is provided with a conductive elastic sheet 30 electrically connected to the circuit board 20, the control key body 40 is arranged on the fixing bracket 10, an outer side of the control key body 40 has a manipulation surface, and an inner side of the control key body 40 is provided with a conductive sheet 50, the conductive sheet 50 is electrically connected to the conductive elastic sheet 30, so that the conductive sheet 50 is electrically connected to the capacitance detecting circuit in the circuit board 20. The manipulation surface of the control key body 40 here is suitable for pressing operation by the user, or can merely be operated by contact.

It is to be noted that the control key 100 described herein is a capacitive sensing touch key. By setting the conductive sheet 50 inside the control key body 40, the conductive sheet 50 is electrically connected to the circuit board 20 through the conductive elastic sheet 30, thereby realizing the path of charge, so that the change in charge of the control key body 40 can be sensed, and then through detection by the software, it is determined whether the user has touched the control key body 40, thereby realizing the touch function of the control key 100.

It can be understood that the detailed working principle of the capacitive sensing touch key is well known to those skilled in the art and will not be described in detail here. The capacitive sensing touch key does not require the human body to directly contact a conductive body, which can completely eliminate safety hazards. They can be used even with gloves, and are not affected by changes in human body resistance such as dry and humid weather, making them more convenient to use.

According to the embodiments of the present application, by setting a conductive elastic sheet 30 on the fixing bracket 10, setting the conductive sheet 50 inside the control key body 40, and using the conductive elastic sheet 30 to realize the electrical connection between the conductive sheet 50 and the circuit board 20, compared with the technical solution using a conductive spring to realize the electrical connection, the control key 100 not only ensures that the conductive elastic sheet 30 and the circuit board 20 can effectively contact, improving the stability of charge conduction, but also improves the hand feeling when touching, thereby improving the user experience.

According to some embodiments of the present application, the control key body 40 is movable relative to the circuit board 20, and the control key body 40 is adapted to move upon being pressed.

For example, when the user presses the manipulation surface inwards, the control key body 40 moves inwards. When the user removes the pressing effect on the manipulation surface, the control key body 40 can move outwards to reset. This not only enables control of the electronic device, but also can improve the manipulation hand feeling and enhance the user experience.

According to other embodiments of the present application, the control key body 40 is rotatable relative to the circuit board 20, and the control key body 40 is adapted to rotate between a first position and a second position upon being pressed.

For example, when the user presses the manipulation surface inwards, the control key body 40 rotates from the first position to the second position. When the user removes the pressing effect on the manipulation surface, the control key body 40 can flip outwards to reset to the first position. This not only enables control of the electronic device, but also can improve the manipulation hand feeling and enhance the user experience.

As shown in FIG. 1, according to some embodiments of the present application, the conductive elastic sheet 30 is located between the circuit board 20 and the fixing bracket 10.

In other words, the conductive elastic sheet 30 is sandwiched between the circuit board 20 and the fixing bracket 10, which not only ensures the installation stability of the conductive elastic sheet 30, but also ensures reliable contact between the conductive elastic sheet 30 and the circuit board 20, thereby effectively improving stability of charge conduction.

According to some embodiments of the present application, the fixing bracket 10 has a mating hole 131, the conductive elastic sheet 30 has a first connecting hole 311, the conductive elastic sheet 30 is fixed to the fixing bracket 10 through a fastener 80, and the fastener 80 passes through the first connecting hole 311 and the mating hole 131, thereby fixing the conductive elastic sheet 30 to the fixing bracket 10, ensuring the installation reliability of the conductive elastic sheet 30 on the fixing bracket 10, so that the conductive elastic sheet 30 can effectively contact the circuit board 20 to improve the stability of charge conduction.

Specifically, as shown in FIGS. 1 to 3, the fixing bracket 10 has a first side and a second side arranged opposite to each other. The circuit board 20 is located on the first side of the fixing bracket 10, and the conductive elastic sheet 30 is located between the circuit board 20 and the first side of the fixing bracket 10. The control key body 40 is located on the second side of the fixing bracket 10, and the conductive sheet 50 is located between the control key body 40 and the second side of the fixing bracket 10.

The first side of the fixing bracket 10 has a concave part 14. The concave part 14 is provided with a fixing pillar 13 protruding from an inner surface of its bottom wall 41. The fixing pillar 13 has a mating hole 131 extending along its axial direction. The mating hole 131 can be a threaded hole. Correspondingly, an end of the conductive elastic sheet 30 is provided with a first connecting hole 311. The fastener 80 can form a screw. The fastener 80 passes through the first connecting hole 311 to mate with the mating hole 131 through thread, thereby fixing the conductive elastic sheet 30 on the fixing bracket 10. The structure is simple and easy to assemble and disassemble.

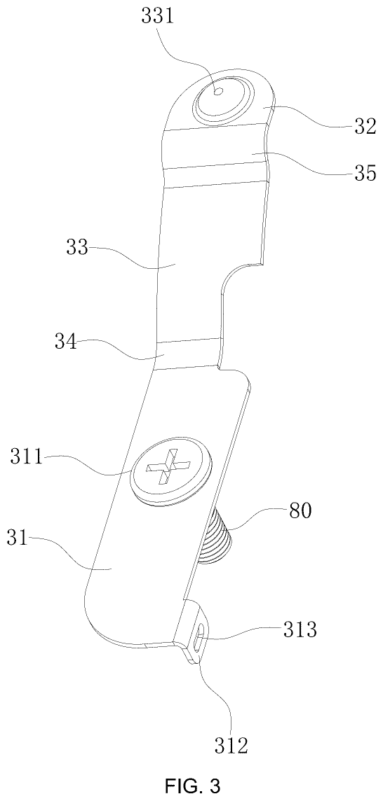

As shown in FIGS. 1 and 3, according to some embodiments of the present application, an end of the conductive elastic sheet 30 is connected to the fixing bracket 10 to form a fixed end, and the other end of the conductive elastic sheet 30 deviates from the fixing bracket 10 to form a free end.

Therefore, by setting the free end of the conductive elastic sheet 30 away from the fixing bracket 10, when the user presses the control key 100, the free end of the conductive elastic sheet 30 can move relative to the fixed end of the conductive elastic sheet 30, thereby improving the touch hand feeling and enhancing the user experience.

The free end of the conductive elastic sheet 30 is provided with a convex part 331, and the convex part 331 contacts and mates with the circuit board 20, so that the conductive elastic sheet 30 and the circuit board 20 can achieve reliable electrical contact, thereby effectively improving the stability of charge conduction.

As shown in FIG. 3, according to some embodiments of the present application, the conductive elastic sheet 30 includes a first conductive segment 31, a second conductive segment 32 and a third conductive segment 33.

The first conductive segment 31 is fixed on the fixing bracket 10, the second conductive segment 32 is electrically connected to the circuit board 20, the third conductive segment 33 is connected between the first conductive segment 31 and the second conductive segment 32, and the third conductive segment 33 extends obliquely towards a direction approaching the circuit board 20 from the first conductive segment 31 to the second conductive segment 31.

Specifically, the first conductive segment 31 and the second conductive segment 32 respectively form a straight segment, and the third conductive segment 33 forms an inclined segment arranged obliquely relative to the straight segment. An end of the first conductive segment 31 is connected to an end of the third conductive segment 33 through a first transitional connecting segment 34, and an end of the second conductive segment 32 is connected to the other end of the third conductive segment 33 through a second transitional connecting segment 35.

The first transitional connecting segment 34 and the second transitional connecting segment 35 may both form arc-shaped connecting segments.

Through the above structural design, the conductive elastic sheet 30 can deform under pressing of the control key body 40. Specifically, the second conductive segment 32 is moved relative to the first conductive segment 31, and a distance between the first conductive segment 31 and the first conductive segment 31 in their thickness direction is shortened. 2, thereby improving the hand feeling when touching and improving the user experience.

As shown in FIG. 3, in embodiments in which the conductive elastic sheet 30 has the first connecting hole 311 and the convex part 331, the first connecting hole 311 is arranged on the first conductive segment 31 and the convex part 331 is arranged on the second conductive segment 32.

As shown in FIG. 1, according to some embodiments of the present application, the conductive sheet 50 is located between the control key body 40 and the fixing bracket 10. In other words, the conductive sheet 50 is sandwiched between the control key body 40 and the fixing bracket 10, which not only ensures the installation stability of the conductive sheet 50, but also ensures that the conductive sheet 50 and the conductive elastic sheet 30 are reliably electrically connected, thereby effectively increasing the stability of charge conduction.

In some embodiments, the control key body 40 defines an accommodating cavity opening at a side, and an outer surface of the bottom wall 41 of the accommodating cavity is adapted to be touched, wherein the conductive sheet 50 is disposed within the accommodating cavity, and the conductive sheet 50 mates with an inner surface of the bottom wall 41 of the accommodating cavity.

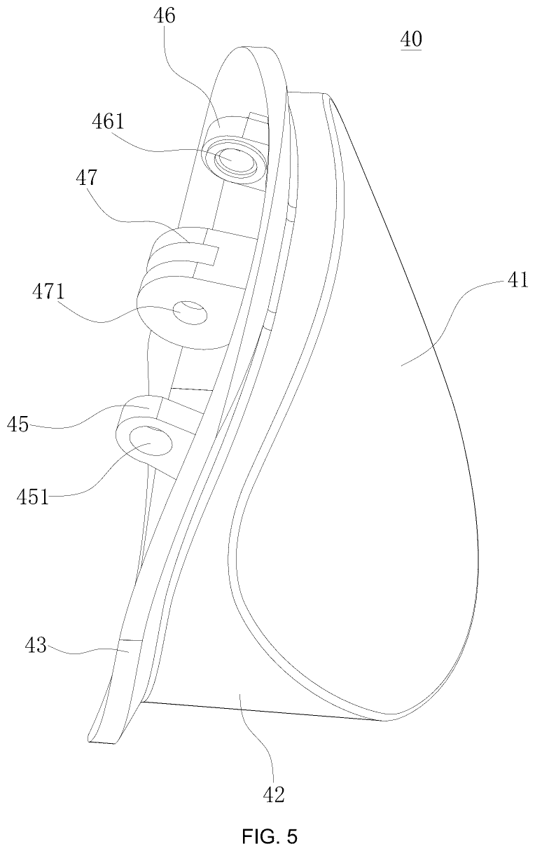

Specifically, as shown in FIG. 5, the control key body 40 includes a bottom wall 41 and a side wall 42. The side wall 42 extends along a circumferential direction of the bottom wall 41. An end of the side wall 42 is connected to the outer periphery of the bottom wall 41. The accommodating cavity is defined between the bottom wall 41 and the side wall 42. The outer surface of the bottom wall 41 of the control key body 40 is adapted to be touched. The conductive sheet 50 is disposed in the accommodating cavity and the conductive sheet 50 is in contact with the inner surface of the bottom wall 41 so that changes in the charge of the control key body 40 can be sensed.

Further, the other end of the side wall 42 of the control key body 40 is provided with a limiting turnup 43 extending along its circumferential direction. After the housing of the electronic device is installed in place, the bottom wall 41 and side wall 42 of the control key body 40 extend out of the mating hole of the housing, exposing the side wall 42 and bottom wall 41 of the control key body 40, and the limiting turnup 43 of the control key body 40 is located inside the housing, thereby preventing the control key body 40 from coming out of the mating hole on the housing.

The outer surface of bottom wall 41 forms a curved surface, which is adapted to be touched, improving the user experience. Correspondingly, the shape of the conductive sheet 50 may be consistent with the shape of the bottom wall 41 of the control key body 40.

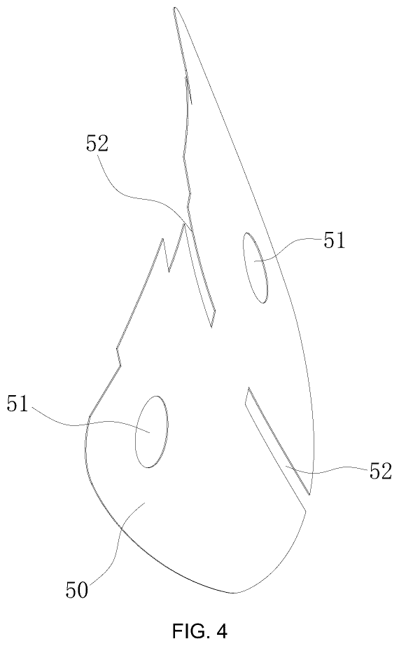

As shown in FIG. 4, in order to ensure the positioning and installation of the conductive sheet 50 on the control key body 40, the conductive sheet 50 is provided with at least two locating holes 51. Correspondingly, the inner side of the control key body 40 is provided with positioning pillars that mate with the locating holes 51. Furthermore, in order to ensure that the conductive sheet 50 can adhere closely to the inner surface of the bottom wall 41 of the control key body 40, kerfs 52 are provided on opposite sides of the conductive sheet 50, so that the conductive sheet 50 can be embedded in the control key body 40.

As shown in FIGS. 1 to 2 and 5, according to further embodiments of the present application, the control key 100 further includes a conductive member 60. The conductive member 60 is located at the fixing bracket 10. The conductive elastic sheet 30 and the conductive sheet 50 are both electrically connected to the conductive member 60.

Therefore, by setting the conductive member 60 on the fixing bracket 10, the electrical connection between the conductive elastic sheet 30 and the conductive sheet 50 is realized, and then the electrical connection between the conductive sheet 50 and the circuit board 20 is realized, and the path of the charge can be realized, so that the change in charge of the control key body 40 can be sensed, and then through detection by the software, it is determined whether the user has touched the control key body 40, thereby realizing the touch function of the control key 100.

In some embodiments, the conductive member 60 forms a conductive shaft, and the control key body 40 is rotatably disposed on the fixing bracket 10 through the conductive shaft. By setting the conductive member 60 to a conductive shaft, using the conductive shaft not only the electrical connection between the conductive elastic sheet 30 and the conductive sheet 50 can be realized, but also the control key body 40 can be rotatably installed on the fixing bracket 10 to realize the assembly of various parts and reduce the number of the parts of the control key 100, simplifying the assembly steps and reducing production costs.

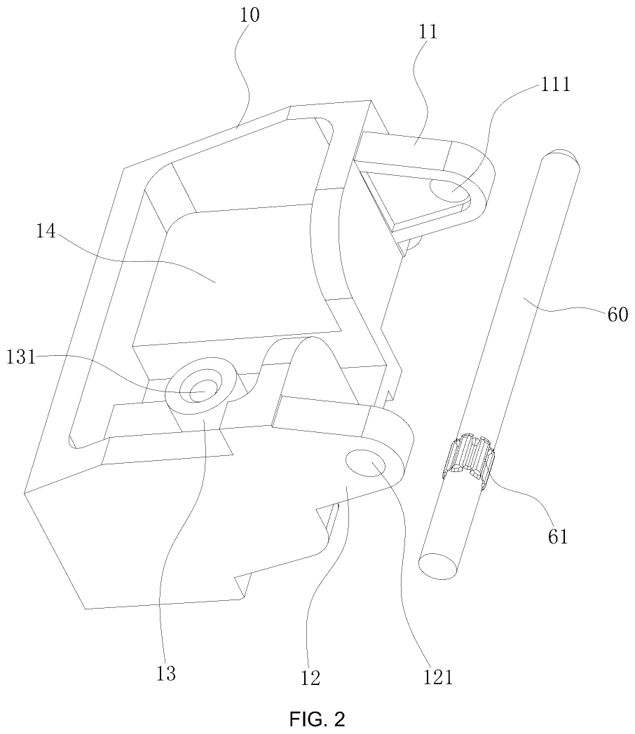

As shown in FIG. 2, in some examples, the fixing bracket 10 is provided with a first fixing lug 11 and a second fixing lug 12 at an interval, the first fixing lug 11 has a first fixing hole 111, and the second fixing lug 12 has a second fixing hole 121, the conductive shaft penetrates the first fixing hole 111 and the second fixing hole 121, thereby fixing the conductive shaft on the fixing bracket 10. The structure is simple and easy to implement.

In some examples, the conductive shaft is in an interference fit with a hole wall of at least one of the first fixing hole 111 and the second fixing hole 121.

As shown in FIG. 2, in this embodiment, the side wall 42 of the conductive shaft is provided with a plurality of protrusions 61 arranged along its circumferential direction. The plurality of protrusions 61 abut against the hole wall of the first fixing hole 111, so that the conductive shaft is in an interference fit with the hole wall of the first fixing hole 111, so that the conductive shaft is fixed on the fixing bracket 10.

Of course, the conductive shaft and the hole wall of the second fixing hole 121 may also have an interference fit; or, the conductive shaft may be in an interference fit with both the hole wall of the first fixing hole 111 and the hole wall of the second fixing hole 121.

It should be noted that in order to ensure the fixed connection between the conductive shaft and the fixing bracket 10, the conductive shaft and the fixing bracket 10 can also be connected using a fastener 80, welding or snap-fit.

In some examples, an inner side of the control key body 40 is provided with a first mounting lug 45 and a second mounting lug 46 arranged at an interval. The first mounting lug 45 has a first mounting hole 451, and the second mounting lug 46 has a second mounting hole 461, the conductive shaft penetrates the first mounting hole 451 and the second mounting hole 461, so that the conductive shaft is installed on the control key body 40, and the control key body 40 is rotatably connected to the fixing bracket 10.

Specifically, as shown in FIG. 5, in this embodiment, a third mounting lug 47 is provided between the first mounting lug 45 and the second mounting lug 46. The third mounting lug 47 has a third mounting hole 471, and the conductive shaft is penetrates the first mounting hole 451, the second mounting hole 461 and the third mounting hole 471, further ensuring the installation reliability and stability of the conductive shaft on the control key body 40.

At least one of the first mounting hole 451, the second mounting hole 461 and the third mounting hole 471 is provided with a bearing, and the conductive shaft mates with the bearing, so that the conductive shaft can rotate relative to the control key body 40.

As shown in FIG. 1, in some embodiments, the conductive member 60 is electrically connected to the conductive elastic sheet 30 through a first conductive wire 71. For example, the conductive member 60 can be fixedly connected to the first conductive wire 71 by means of screwing, snap-fitting or welding, and the conductive elastic sheet 30 can be fixedly connected to the first conductive wire 71, so that electrical conduction can be achieved at the same time, simplifying processing and assembly.

As shown in FIGS. 1 and 3, in some examples, an end of the conductive elastic sheet 30 is provided with a connecting turnup 312 bent towards the control key body 40. That is, an end of the connecting turnup 312 is connected to the conductive elastic sheet 30, and the other end of the connecting turnup 312 extends towards the control key body 40. The connecting turnup 312 has a second connecting hole 313, an end of the first conductive wire 71 is hung on the second connecting hole 313, and the other end of the first conductive wire 71 is electrically connected to the conductive member 60, thereby fixedly connecting the first conductive wire 71 to the conductive elastic sheet 30, the structure is simple, and easy to assembly and disassembly.

In some embodiments, the conductive member 60 is electrically connected to the conductive sheet 50 through a second conductive wire 72. For example, the conductive member 60 can be fixedly connected to the second conductive wire 72 by screwing, snap-fitting or welding, and the conductive sheet 50 can be fixedly connected to the second conductive wire 72, thereby achieving electrical conduction and simplifying processing and assembly at the same time.

The conductive elastic sheet 30, the conductive sheet 50, the conductive member 60, the first conductive wire 71, and the second conductive wire 72 are all made of metal materials as components of the charge path, and have good structural reliability and long service life. Of course, the present application is not limited thereto. The conductive elastic sheet 30, the conductive sheet 50, the conductive member 60, the first conductive wire 71, and the second conductive wire 72 can also be made of other conductive materials, such as conductive plastic, conductive rubber, etc.

It is to be noted that the control key 100 described herein is a capacitive sensing control key 100. By setting the conductive member 60 inside the insulating part, the conductive member 60 is electrically connected to the circuit board 20 through the conductive spring and the conductive bracket, thereby realizing the path of the charge, so that the change in charge of the control key body 40 can be sensed, and then through detection by the software, it is determined whether the user has touched the control key body 40, thereby realizing the touch function of the control key 100. It can be understood that the detailed working principle of the capacitive control key 100 is well known to those skilled in the art and will not be described in detail here.

The electronic device according to the embodiments of the present application will be described below with reference to the accompanying drawings.

The electronic device according to the embodiments of the present application includes a device body and a control key 100 according to the above embodiments. The control key 100 is disposed on the device body.

Since the control key 100 according to the embodiments of the present application has the above technical effects, the electronic device according to the embodiments of the present application also has the above technical effects, which can improve the overall touch performance of the electronic device.

It should be noted that the specific type of the device body is not limited. For example, it can be an AR device or a VR device, which can include a helmet part and a handle part. The control key 100 can be located at a desired position such as the helmet part or the handle part, so that it can improve the overall touch experience of the electronic device.

In addition, after the specific type of the electronic device of the embodiments of the present application is determined, other components and operations of the device body are known to those of ordinary skill in the art and will not be described in detail here.

In the description of the present application, it should be understood that the orientation or positional relationships indicated by the terms “axial”, “radial”, “circumferential”, etc. are based on the orientation or positional relationship shown in the drawings, and are only for ease of describing the present application and simplifying the description, but are not intended to indicate or imply that the components or elements referred to must have a particular orientation, be constructed and operate in a particular orientation, and therefore are not to be construed as limitations of the present application.

In addition, the terms “first” and “second” are used for descriptive purposes only and cannot be understood as indicating or implying relative importance or implicitly indicating the quantity of indicated technical features. Therefore, features defined as “first” and “second” may explicitly or implicitly include one or more of these features. In the description of the present application, “plurality” means two or more than two, unless otherwise explicitly and specifically limited.

In the present application, unless otherwise clearly stated and limited, the terms “installation”, “connecting”, “connection”, “fixing” and other terms should be understood in a broad sense. For example, it can be a fixed connection or a detachable connection, or integrated; it can be a mechanical connection, an electrical connection, or a communication; it can be a direct connection, or an indirect connection through an intermediate medium, or an internal connection between two elements or an interaction between two elements. For those of ordinary skill in the art, the specific meanings of the above terms in the present application can be understood according to specific circumstances.

In the present application, unless otherwise expressly stated and limited, a first feature being “on” or “below” a second feature may mean that the first and second features are in direct contact, or the first and second features are in indirect contact through an intermediary media. Furthermore, a first feature being “above”, “over” and “overly” the second feature may mean that the first feature is directly above or diagonally above the second feature, or simply means that the first feature is higher in level than the second feature. A first feature being “below”, under” and “beneath” the second feature may mean that the first feature is directly below or diagonally below the second feature, or simply means that the first feature has a smaller horizontal height than the second feature.

In the description of this specification, reference to the description of the terms “an embodiment”, “some embodiments”, “example”, “specific examples”, or “some examples”, etc. means that the specific features, structures, materials or characteristics, etc. described in connection with the embodiments or examples are included in at least one embodiment or example in the present application. In this specification, schematic expressions of the above terms do not necessarily refer to the same embodiments or examples. Furthermore, the specific features, structures, materials or characteristics described may be combined in any suitable manner in any one or more embodiments or examples. Furthermore, those skilled in the art may integrate and combine different embodiments or examples described in this specification and features of different embodiments or examples unless they are inconsistent with each other.

Although the embodiments of the present application have been shown and described, those of ordinary skill in the art will understand that various changes, modifications, substitutions and modifications can be made to these embodiments without departing from the principles and purposes of the present application. The scope of is defined by claims and their equivalents.

1. A control key, comprising:
a circuit board having a capacitance detecting circuit therein;
a fixing bracket provided with a conductive elastic sheet, the conductive elastic sheet being electrically connected to the circuit board;
a control key body disposed on the fixing bracket, an outer side of the control key body having a manipulation surface and an inner side of the control key body being provided with a conductive sheet, the conductive sheet being electrically connected to the conductive elastic sheet, such that the conductive sheet is electrically connected to the capacitance detecting circuit.

2. The control key of claim 1, wherein the control key body is movable or rotatable relative to the circuit board, and the control key body is adapted to move or rotate upon being pressed.

3. The control key of claim 1, wherein the conductive elastic sheet is located between the circuit board and the fixing bracket.

4. The control key of claim 1, wherein the fixing bracket has a mating hole, the conductive elastic sheet has a first connecting hole, the conductive elastic sheet is fixed to the fixing bracket through a fastener, and the fastener passes through the first connecting hole and the mating hole.

5. The control key of claim 1, wherein an end of the conductive elastic sheet is connected to the fixing bracket to form a fixed end, and the other end of the conductive elastic sheet deviates from the fixing bracket to form a free end, the free end of the conductive elastic sheet is provided with a convex part, and the convex part is in contact with and mates with the circuit board.

6. The control key of claim 1, wherein the conductive elastic sheet comprises:
a first conductive segment fixed on the fixing bracket;
a second conductive segment electrically connected to the circuit board;
a third conductive segment connected between the first conductive segment and the second conductive segment, the third conductive segment extending obliquely towards a direction approaching the circuit board from the first conductive segment to the second conductive segment.

7. The control key of claim 1, wherein the conductive sheet is located between the control key body and the fixing bracket.

8. The control key of claim 7, wherein the control key body defines an accommodating cavity opening at a side, and an outer surface of a bottom wall of the accommodating cavity is adapted to be touched,
wherein the conductive sheet is disposed within the accommodating cavity and mates with an inner surface of the bottom wall of the accommodating cavity.

9. The control key of claim 1, further comprising:
a conductive member disposed on the fixing bracket, both the conductive elastic sheet and the conductive sheet are electrically connected to the conductive member.

10. The control key of claim 9, wherein the conductive member forms a conductive shaft, and the control key body is rotatably disposed on the fixing bracket through the conductive shaft.

11. The control key of claim 10, wherein the fixing bracket is provided with a first fixing lug and a second fixing lug arranged at an interval, the first fixing lug has a first fixing hole and the second fixing lug has a second fixing hole, the conductive shaft penetrates the first fixing hole and the second fixing hole.

12. The control key of claim 11, wherein the conductive shaft is in an interference fit with a hole wall of at least one of the first fixing hole and the second fixing hole.

13. The control key of claim 10, wherein the inner side of the control key body is provided with a first mounting lug and a second mounting lug arranged at an interval, the first mounting lug has a first mounting hole and the second mounting lug has a second mounting hole, and the conductive shaft passes through the first mounting hole and the second mounting hole.

14. The control key of claim 9, wherein the conductive member is electrically connected to the conductive elastic sheet through a first conductive wire, and the conductive member is electrically connected to the conductive sheet through a second conductive wire.

15. The control key of claim 14, wherein an end of the conductive elastic sheet is provided with a connecting turnup bent towards the control key body, the connecting turnup has a second connecting hole, and an end the first conductive wire is hung on the second connecting hole and the other end is electrically connected to the conductive member.

16. An electronic device, comprising a device body and a control key the control key being disposed in the device body and comprising:
a circuit board having a capacitance detecting circuit therein;
a fixing bracket provided with a conductive elastic sheet, the conductive elastic sheet being electrically connected to the circuit board;
a control key body disposed on the fixing bracket, an outer side of the control key body having a manipulation surface and an inner side of the control key body being provided with a conductive sheet, the conductive sheet being electrically connected to the conductive elastic sheet, such that the conductive sheet is electrically connected to the capacitance detecting circuit.

17. The electronic device of claim 16, wherein the control key body is movable or rotatable relative to the circuit board, and the control key body is adapted to move or rotate upon being pressed.

18. The electronic device of claim 16, wherein the fixing bracket has a mating hole, the conductive elastic sheet has a first connecting hole, the conductive elastic sheet is fixed to the fixing bracket through a fastener, and the fastener passes through the first connecting hole and the mating hole.

19. The electronic device of claim 16, wherein an end of the conductive elastic sheet is connected to the fixing bracket to form a fixed end, and the other end of the conductive elastic sheet deviates from the fixing bracket to form a free end, the free end of the conductive elastic sheet is provided with a convex part, and the convex part is in contact with and mates with the circuit board.

20. The electronic device of claim 16, wherein the conductive elastic sheet comprises:
a first conductive segment fixed on the fixing bracket;
a second conductive segment electrically connected to the circuit board;
a third conductive segment connected between the first conductive segment and the second conductive segment, the third conductive segment extending obliquely towards a direction approaching the circuit board from the first conductive segment to the second conductive segment.
